(19) United States
(12) Patent Application Publication
(10) Pub. No.: US 2010/0203924 A1
(43) Pub. Date: Aug. 12, 2010

(54) Electronic Device and Mobile Phone

(75) Inventor: Hiroyuki Hirota, Kanagawa (JP)

Correspondence Address: Hogan Lovells US LLP, 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 12/440,435

(22) PCT Filed: Sep. 7, 2007
(86) PCT No.: PCT/JP2007/067469

§ 371 Date: Apr. 15, 2010

(30) Foreign Application Priority Data
Sep. 8, 2006 (JP) 2006-244835

(51) Int. Cl. H04M 1/02; H05K 5/00

(52) U.S. Cl. 455/566; 361/679.01

(57) ABSTRACT

An electronic device in which a protective plate has sufficient bonding strength and that has improved ease of disassembly and a mobile phone having the electronic device. The electronic device has a housing 102 with an opening 116, a mounting member (reinforcement plate 117) arranged on an inner circumference of the housing opening 116 and mounted on the housing 102, a cover (protective plate 113) adhered and fastened to a peripheral edge (bottom part 115) of the housing opening 116 of the housing 102 and to the mounting member (reinforcement plate 117) and closing the housing opening 116 of the housing 102, and a display device 120 arranged inside the housing 102 so as to face the cover (protective plate 113) with at least a portion of the display inserted in the opening 116.

### TECHNICAL FIELD

The present invention relates to an electronic device and a mobile phone having a display.

### BACKGROUND ART

Conventionally, as shown in FIG. 6, a protective plate 2 made of an acrylic resin or the like used as a cover which covers and protects a display of a mobile phone is adhered and fastened to a bottom part 6 of a front case 4a by two-sided tape 8 etc. (see for example Patent Document 1).

However, mobile phones are being made increasingly thinner and larger in screens. As shown in FIG. 6, it is becoming difficult to secure an area of the bottom part 6 of the front case 4a for joining the protective plate 2, the area for arranging the two-sided tape B for adhering the protective plate is reduced, and therefore the adhesion strength is falling as a general trend. In such a case, the impact due to dropping of the mobile phone is liable to cause the protective plate 2 to detach.

For this reason, as shown in FIG. 7, in a structure of a display 10 of a thin type mobile phone, in order to enlarge the area for arrangement of the two-sided tape 8 fastening the protective plate 2, the method of adhering the two-sided tape 8 from the bottom part 6 of the front case 4a up to the front surface of the end of the display 10 may be employed.

### Patent Document 1: Japanese Patent Publication No. 09-283950

### DISCLOSURE OF THE INVENTION

### Problem to be Solved by the Invention

However, if using two-sided tape 8 to adhere the protective plate 2 to the display 10, when removing the protective plate 2 when disassembling the mobile phone for repair etc., however the display 10 was liable to be broken.

An object of the present invention is to provide an electronic device and a mobile phone in which the adhesion strength of the cover and ease of disassembly are improved.

### Means for Solving the Problem

An electronic device in the present invention has a housing with an opening, a mounting member arranged at an inner circumference of the opening and mounted on the housing, a cover adhered to a peripheral edge of the opening of the housing and to the mounting member and covering the opening, and a display arranged inside the housing so as to face the cover in a state at least partially inserted in the opening.

Preferably, the thickness of the mounting member is thinner than the thickness of the peripheral edge of the opening.

Preferably, the housing has a recess which is recessed inwardly and in which the opening is formed, and the cover is fit in the recess.

Preferably, the mounting member is arranged so that a bonding surface with the cover in the mounting member and a bonding surface with the cover at the peripheral edge of the opening become the same plane.

Preferably, the housing has a limit member limiting movement of the mounting member in an outward direction of the housing.

Preferably, the mounting member has conductivity and is connected to a ground part being inside the housing.

Preferably, the display is arranged inside the housing in a state abutting against a surface, which is on the inside of the housing, of the mounting member.

Preferably, the housing has a case member in which the opening is formed, the case member has projecting parts formed to project out to the inside of the housing, and the mounting member is clamped by the projecting parts and a circuit board arranged inside the housing.

Preferably, the mounting member has a plate-shaped bonding part which is arranged at the inner circumference of the opening and is bonded with the cover, and the bonding part is arranged over the entire periphery of the opening.

Preferably, the device has a housing accommodating a display and circuit board and in which an opening is formed, a mounting member arranged at an inner circumference of the opening, and a cover covering the opening, wherein the mounting member is mounted on the housing, the cover is bonded to a peripheral edge of the opening of the housing and to the mounting member, and the display is arranged inside the housing so as to face the cover in a state at least partially inserted in the opening.

A mobile phone in the present invention has a housing having an operation key, a microphone, and a speaker, wherein the receiver housing is provided with a case member having an opening formed therein, a mounting member arranged at an inner circumference of the opening and mounted on the case member, a cover bonded to a peripheral edge of the opening of the case member and to the mounting member and covering the opening, and a display arranged inside the housing so as to face the cover in a state at least partially inserted in the opening.

### EFFECT OF THE INVENTION

According to the present invention, an electronic device and a mobile phone in which the adhesion strength of the cover and the ease of disassembly are improved can be provided.

### BRIEF DESCRIPTION OF THE DRAWINGS

FIG. 1 is a perspective view showing an appearance of a mobile phone in the present embodiment according to the present invention.

FIG. 2 is a disassembled view showing the configuration of a receiver housing.

FIG. 3 is a diagram explaining a method of fastening a reinforcement plate and a front case in the present embodiment according to the present invention.

FIG. 4 is a cross-sectional view showing an IV-IV cross-section in FIG. 1.

FIG. 5 is an enlarged view of a cross-sectional view showing the IV-IV cross-section of a part where the reinforcement plate and the front case are engaged in FIG. 1.

FIG. 6 is an explanatory diagram for explaining the prior art.

FIG. 7 is an explanatory diagram for explaining the prior art.

### EXPLANATION OF NOTATIONS

100 . . . mobile phone, 101 . . . transmitter housing, 102 . . . receiver housing (housing), 102a . . . front case (case member), 102b . . . rear case, 103 . . . hinge, 104 . . . front surface, 110 . . . microphone, 111 . . . operation keys, 112 . . . speaker, 113 . . . protective plate (cover), 113a . . . outer circumference, 114 . . . two-sided tape, 114a . . . tape opening, 115 . . . bottom part (peripheral edge), 116 . . . housing opening (opening), 117 . . . reinforcement plate (mounting member), 117a . . . flat part (bonding part), 117b . . . mounting part, 118 . . . top surface (bonding surface), 119 . . . reinforcement plate opening, 120 . . . display device, 121 . . . display portion, 122 . . . front end part, 123 . . . projecting part (limit member, salience part), 124 . . . bent part, 125 . . . top surface (bonding surface), 130 . . . recess, 131 . . . circuit board (circuit board)

### BEST MODE FOR CARRYING OUT THE INVENTION

The present invention can be applied to a variety of electronic devices, in particular can be preferably applied to portable type electronic devices, for example mobile phones, small-sized audio players or video players/recorders, portable television, and other electronic devices where smaller size and thinner shape are being demanded.

As an embodiment of the electronic device according to the present invention, a mobile phone will be explained as an example with reference to the attached drawings.

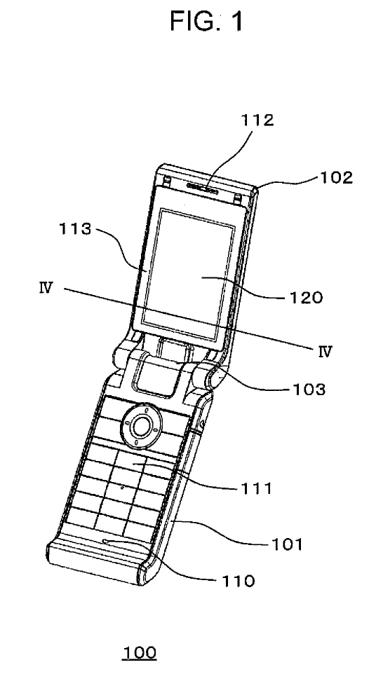

FIG. 1 is a perspective view showing an appearance of a mobile phone 100 in the present embodiment according to the present invention. The mobile phone 100 has a key side housing (hereinafter also referred to as a “transmitter housing”) 101, a display side housing (hereinafter also referred to as a “receiver housing”) 102, and a hinge 103 connecting the transmitter housing 101 and the receiver housing 102.

The transmitter housing 101 has a microphone 110 and operation keys 111 on a front surface 104. The operation keys 111 are comprised of various types of keys, for example, ten keys, cursor keys, function keys, and an execute key. The microphone 110 is provided near the front end of the transmitter housing 101 (lower part in the figure) below the operation keys 111, converts input audio to an electrical signal, and outputs the electrical signal to an electronic controller on a not shown circuit board arranged in the transmitter housing 101.

The receiver housing 102 has, on the front surface 104, a speaker 112, a display device 120 displaying an image, text, etc., and a protective plate 113 serving as a cover covering the display device 120 so as to protect the display device 120. The speaker 112 is provided near the front end of the receiver housing 102 (upper part in the figure) above the display device 120, converts any audio electrical signal relating to audio speech output from a communication part arranged on the circuit board in the transmitter housing 101 which is input to audio, and outputs the audio to the outside of the housing. The display device 120 is arranged inside the receiver housing 102 so that the display portion 121 is located at the substantial center of the front surface 104 of the receiver housing 102. The protective plate 113 is adhered and fastened to the front surface 104 of the receiver housing 102 so as to cover the display device 120. This display device 120 is configured by, for example, a liquid crystal display device (LCD), an organic EL display device, or other display device and displays images, text, etc. on the display portion 121.

The hinge 103 connects the transmitter housing 101 and the receiver housing 102 and enables the mobile phone 100 to be opened/closed about the hinge 103.

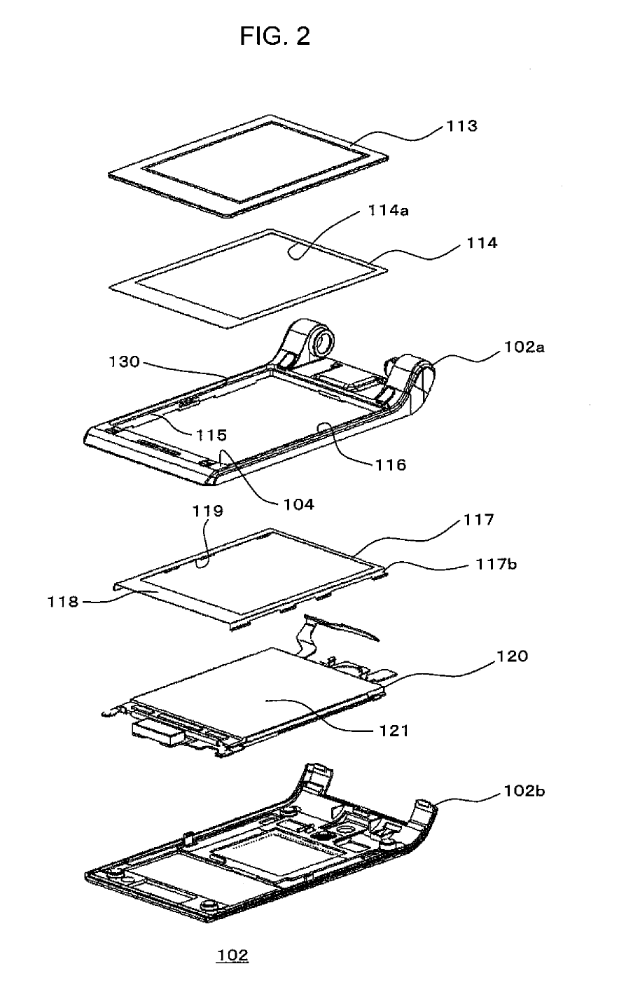

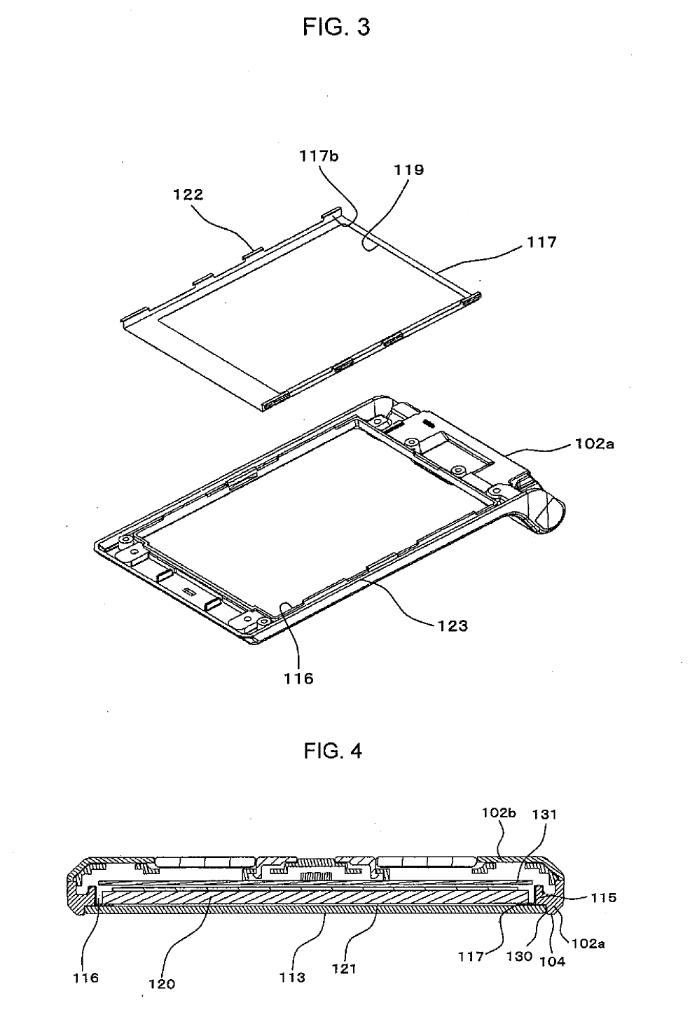

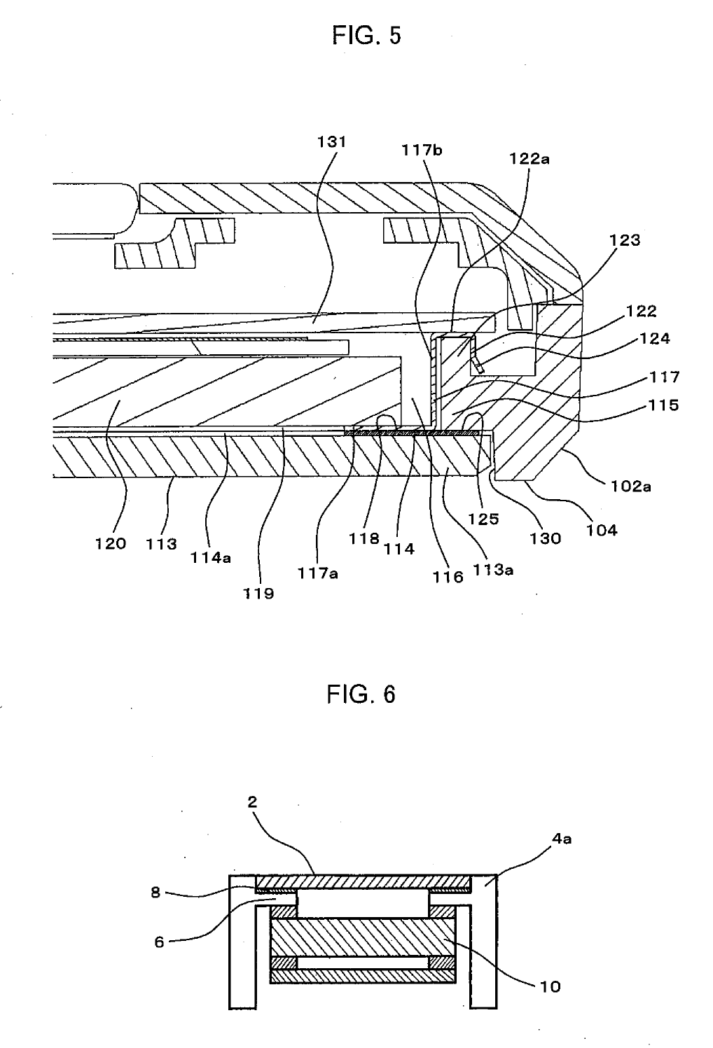

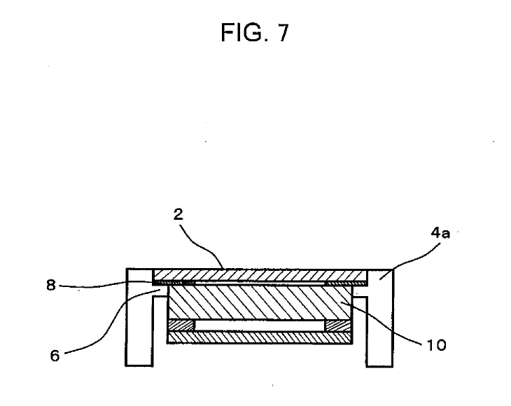

FIG. 2 is a disassembled view showing the configuration of the receiver housing 102. FIG. 3 is a disassembled perspective view of a reinforcement plate 117 used as the mounting member in the receiver housing 102 and a front case 102a constituting the receiver housing 102. FIG. 4 is a cross-sectional view showing an IV-IV cross-section in FIG. 1, and FIG. 5 is an enlarged view of the cross-sectional view showing the IV-IV cross-section of a part where the reinforcement plate and the front case are engaged in FIG. 1.

As shown in FIG. 2, the receiver housing 102 is comprised having a protective plate 113, two-sided tape 114, front case 102a constituting the receiver housing 102, reinforcement plate 117, display device 120, and rear case 102b constituting the receiver housing 102. In the front case 102a, a recess 130 recessed to the inside of the housing is formed in the front surface 104, and an housing opening 116 is formed in a bottom part 115 of the recess 130. Namely, the peripheral edge of the housing opening 116 is formed by the bottom part (peripheral edge) 115.

The protective plate 113 is rectangular or square in shape, is formed by, for example, an acrylic resin, reinforced glass, or the like, and is inserted into the recess 130 so as to cover the housing opening 116 of the front case 102a. Further, the protective plate 113 is adhered and fastened to the front case 102a by the two-sided tape 114 arranged between the inner surface of the outer circumference 113a on the housing side and the top surface (bottom face in FIG. 5) 125 of the bottom part 115 of the recess 130.

Further, as shown in FIG. 4 and FIG. 5, a circuit board 131 is arranged in the receiver housing 102. The circuit board 131 is comprised so that it is clamped, positioned, and fastened by the two cases 102a and 102b by connection of the front case 102a and the rear case 102b. The display device 120 is accommodated inside the housing between this circuit board 131 and the front case 102a. The display device 120 is disposed so that a portion on the front case 102a side is inserted in the housing opening 116 formed in the bottom part 115 of the recess 130 of the front case 102a and so that the display portion 121 is exposed at the outside of the front case 102a through the housing opening 116. The protective plate 113 is mounted in the recess 130 of the front case 102a, therefore the display portion 121 of the display device 120 and the protective plate 113 are arranged to face each other. Accordingly, the protective plate 113 closes the housing opening 116 of the front case 102a and covers the display portion 121 of the display device 120, so the display portion 121 will not be exposed to the outside of the housing. Accordingly, the display portion 121 of the display device 120 is covered and protected by the protective plate 113 adhered and fastened to the bottom part 115 of the recess 130 of the front case 102a by the two-sided tape 114.

As shown in FIG. 2 to FIG. 5, in the housing opening 116 formed in the front case 102a, a portion of the display device 120 is inserted, and the reinforcement plate 117 used as the mounting member mounted on the front case 102a is arranged on the inner circumference thereof. The reinforcement plate 117 is constituted by having a flat part 117a formed parallel to a display surface (bottom surface in FIG. 5) of the display portion 121 of the display device 120, and mounting parts 117b vertically bent from the outer peripheral end of this flat part 117a and extended to the inside of the housing. The flat part 117a is formed in a frame-shaped rectangular or square shape having an reinforcement plate opening 119 inside it so that its outer periphery (size of frame) becomes larger than the outer periphery of the display device 120, but a little smaller than the housing opening 116 of the front case 102a. Further, the reinforcement plate 117 is constituted so that the flat part 117a is positioned on the inner circumference of the housing opening 116 of the front case 102a over the entire periphery on the outer side of the front case 102a (lower side shown in FIG. 5) than the display portion 121 of the display device 120. Note that, the reinforcement plate 117 is constituted by a metal or other material having conductivity and is formed by sheet metal in the present embodiment. Other than this, it may be constituted by a polycarbonate, polyethylene, or other insulating resin as well. In this case, however, in order to maintain a state where the reinforcement plate 117 is made conductive with the ground part of the circuit board 131, preferably conductive paint or metal vapor deposition is applied to the outer face to provide conductivity.

Next, the mounting structure of the reinforcement plate 117 on the front case 102a will be explained in detail. As shown in FIG. 5, in the front case 102a, projecting parts 123 projecting out to the inside of the housing are formed on the bottom part 115 of the recess 130. The mounting parts 117b extending from the outer peripheral end of the flat part 117a of the reinforcement plate 117 to the inside of the housing are formed so that their front end parts 122 have an approximately U-shaped cross-section along the projecting parts 123. Further, by fitting the front end parts 122 of the mounting parts 117b formed in an approximately U-shaped cross-section with the projecting parts 123 of the front case 102a, the reinforcement plate 117 is mounted and fastened to the front case 102a. Note that, as shown in FIG. 5, the front ends of the front end parts 122 of the mounting parts 117b formed in an approximately U-shaped cross-section have bent parts 124 bent in the width direction of the housing (rightward direction of FIG. 5). Further, the front end parts 122 of the mounting parts 117b are shaped so that the front end parts 122 can be easily fit with the projecting parts 123.

The mounting parts 117b and the projecting parts 123 are provided at the two sides in the width direction of the housing. Therefore, when the mounting parts 117b are fit with the projecting parts 123 at the two sides in the width direction, the bent parts 124 press against the projecting parts 123 to the inside of the width direction of the housing. As a result, the reinforcement plate 117 clamps the front case 102a by the mounting parts 117b at the two ends in the width direction of the housing and is mounted on the front case 102a positioned with respect to the width direction of the housing.

Note that the front end parts 122 of the mounting parts 117b formed in an approximately U-shaped cross-section may be constituted to be shaped so that the spaces in the width direction of the housing (left/right direction in FIG. 5) become shorter than the lengths of the projecting parts 123 in the width direction and so as to clamp the projecting parts 123 when fit with the projecting parts 123. In this case, the mounting of the reinforcement plate 117 on the front case 102a can be made stronger. When the mounting parts 117b are fit with the projecting parts 123, the bottom parts 122a (top end faces shown in FIG. 5) of the front end parts 122 of the mounting parts 117b are engaged with the front end faces (top end faces shown in FIG. 5) of the projecting parts 123. As a result, the reinforcement plate 117 is mounted and fastened to the front case 102a in a state where movement in the outward direction of the housing (downward direction shown in FIG. 5) is limited with respect to the front case 102a (at least one of the mounting parts 117b and the projecting parts 123 constitutes the limit member in the present invention).

By engaging the bottom parts 122a of the front end parts 122 of the mounting parts 117b with the front end faces of the projecting parts 123 and the fitting the mounting parts 117b with the projecting parts 123, in the state where the reinforcement plate 117 is mounted on the front case 102a, the flat part 117a of the reinforcement plate 117 is arranged so that its top surface (bottom surface shown in FIG. 5) 118 on the outside of the housing becomes substantially the same plane as the top surface (bonding surface) 125 on the outside of the housing of the bottom part 115 of the front case 102a. Further, the flat part 117a of the reinforcement plate 117 is formed so that its thickness becomes sufficiently thinner than the thickness (height in the up/down direction shown in FIG. 5) of the bottom part 115 of the front case 102a. Further, the reinforcement plate opening 119 formed on the flat part 117a is formed to become a little smaller than the outer periphery of the display portion 121 of the display device 120.

The front case 102a on which the reinforcement plate 117 is mounted in this way is provided with the protective plate 113 inserted in the recess 130. Between the back surface (top surface in FIG. 5) on the inside of the housing of the outer circumference 113a of this protective plate 113 and the bottom part 115 of the recess 130 of the front case 102a, the two-sided tape 114 is disposed. This two-sided tape 114 is constituted by, for example, a synthetic rubber-based or acrylic tackifier. It is constituted by a material equivalent to the conventional one, so a detailed explanation is omitted. This two-sided tape 114 is formed in a square shape inside which an tape opening 114a is formed. Further, in the two-sided tape 114, the tape opening 114a is substantially the same size as that of the reinforcement plate opening 119 formed in the reinforcement plate 117. Further, the two-sided tape 114 is formed to a shape so that its outer circumference becomes substantially the same as the outer periphery of the protective plate 113 or bottom part 115.

The two-sided tape 114 is adhered to the front case 102a, on which the reinforcement plate 117 is arranged so that the top surface (bonding surface) 118 of the flat part 117a of the reinforcement plate 117 becomes substantially the same plane as the top surface 125 of the bottom part 115 of the front case 102a, over the top surface 118 of the flat part 117a and the top surface 125 of the bottom part 115 so that the tape opening 114a matches with the reinforcement plate opening 119 of the reinforcement plate 117. Further, by insertion of the protective plate 113 in the recess 130 of the front case 102a and bonding of the back surface (top face shown in FIG. 5) of the outer circumference 113a of the protective plate 113 with the two-sided tape 114, the protective plate 113 is mounted on the front case 102a. Note that the two-sided tape 114 is formed to a thickness so that the front surface (bottom face shown in FIG. 5) of the protective plate 113 becomes the same plane as the front surface 104 of the front case 102a in a state where the protective plate 113 is mounted on the front case 102a.

The protective plate 113 is constituted by an acrylic plate or reinforced glass or other material having translucency. However, the outer circumference 113a to which the two-sided tape 114 is bonded is printed on, so the state of bonding with the two-sided tape 114 cannot be seen from the outside of the housing.

Next, the assembly of the receiver housing 102 of the mobile phone 100 configured by above components will be explained.

First, as shown in FIG. 3, the reinforcement plate 117 is mounted on the front case 102a from the inner surface (top surface shown in FIG. 3) side of the housing of the front case 102a. At this time, the flat part 117a of the reinforcement plate 117 is inserted in the housing opening 116 of the front housing 102 and the mounting parts 117b of the reinforcement plate 117 are engaged with the projecting parts 123 formed on the inside of the housing of the bottom part 115 of the front housing 102 as explained above, whereby the reinforcement plate 117 is mounted on the front case 102a. Further, the flat part 117a of the reinforcement plate 117 is arranged so as to become the same plane as the top surface 125 of the bottom part 115 of the front case 102a. Further, as shown in FIG. 2, on the front case 102a on which this reinforcement plate 117 is mounted, the two-sided tape 114 is adhered to the bottom part 115 of the recess 130 of the front housing 102 and the flat part 117a of the reinforcement plate 117 from the outside of the housing.

Further, the protective plate 113 is inserted into the recess 130 of the front case 102a, whereby the inner surface of the outer circumference 113a of the protective plate 113 is adhered to the outer surface (top face in FIG. 2) of the two-sided tape 114. Accordingly, the housing opening 116 formed in the front case 102a is closed by the protective plate 113. Further, the top surface (bottom surface shown in FIG. 5) of the flat part 117a of the reinforcement plate 117 is disposed so as to become on the same plane as the top surface 125 of the bottom part 115 of the front case 102a, therefore the mounting of the protective plate 113 on the front case 102a by the two-sided tape 114 can be made stronger. Further, in this state, the front surface (top surface in FIG. 2) of the protective plate 113 is located on the same plane as the front surface 104 used as the outer surface of the front case 102a as explained above.

Next, the display portion 121 of the display device 120 is inserted into the housing opening 116 of the front case 102a from the inner surface side of the housing of the front case 102a, and the display device 120 is mounted on the inner surface of the front case 102a. Note that the mounting parts 117b of the reinforcement plate 117 are inserted and arranged in the housing opening 116 of the front case 102a, therefore the display device 120 is arranged so as to be inserted and fitted in the mounting parts 117b. Further, the flat part 117a of reinforcement plate 117 is arranged on the outside of the housing of the housing opening 116, but the display portion 121 inserted in the housing opening 116 is mounted so that the display region on its display surface matches with the reinforcement plate opening 119 of the flat part 117a. Note that the inner frame of the tape opening 114a of the two-sided tape 114 and the inner frame of the print region (outer frame region of the protective plate 113 in FIG. 2) of the protective plate 113 are formed along the inner frame of the reinforcement plate opening 119 of the flat part 117a of the reinforcement plate 117. For this reason, the display device 120 is mounted on the front case 102a so that the display region of the display portion 121 is not covered by the flat part 117a of the reinforcement plate 117 and the two-sided tape 114 and the print region of the protective plate 113.

Further, between the outer surface side of the housing of the display device 120 and the protective plate 113, the flat part 117a of the reinforcement plate 117 mounted on the front case 102a is arranged so as to become substantially the same plane as the top surface 125 of the bottom part 115 of the front case 102a. The two-sided tape 114 is arranged over the flat part 117a and the top surface 125 of the bottom part 115, therefore the protective plate 113 can be adhered and mounted on the front case 102a without reduction of the bonding area of the protective plate 113 to the front case 102a. Further, by provision of the reinforcement plate 117, direct adhesion of the two-sided tape 114 to the display device 120 can be avoided.

Further, by employing a constitution making the thickness of the flat part 117a of the reinforcement plate 117 sufficiently thinner than the thickness of the bottom part 115 forming the housing opening 116 of the front case 102a, the protective plate 113 and the display device 120 can be arranged close in the housing by inserting the display device 120 into the housing opening 116 after securing the adhesion region of the two-sided tape 114, therefore the constitution of the receiver housing 102 having the front case 102a can be made thin. Note that a receiver and other electronic parts are mounted on the front case 102a together with the mounting of the display device 120.

Next, in the state where the display device 120 is mounted on the front case 102a, the circuit board 131 is attached on the front case 102a from the inside of the housing. On the inner surface of the front case 102a, not shown engaging tabs are formed. Then, by engagement of the outer peripheral end of the circuit board 131 with the engaging tabs, the circuit board 131 is mounted and fastened on the front case 102a. After the circuit board 131 is mounted on the front case 102a, connection cables provided at the display device 120, receiver, etc. are connected to the connector or other connection part provided on the circuit board 131. In the state where the circuit board 131 is mounted on the front case 102a, the end of the circuit board 131 is made to abut against the mounting parts 117b of the reinforcement plate 117. Accordingly, in this state, the mounting parts 117b of the reinforcement plate 117 are clamped between the circuit board 131 and the projecting parts 123 of the front case 102a. Further, the circuit board 131 is formed with a ground part (reference potential part) at a position facing the projecting parts 123 on the front surface on the display device 120 side. Accordingly, when the circuit board 131 is mounted on the front case 102a, the reinforcement plate 117 formed by metal sheet is made conductively connected with the ground part of the circuit board 131.

Next, on the back surface (top face in FIG. 4 and FIG. 5) of the circuit board 131, a sub-display device and a camera module etc. are arranged at positions corresponding to a display window and a camera window of the rear case 102b. Further, the rear case 102b of the receiver housing 102 is connected with the front case 102a. The connection structure of these cases 102a and 102b need only be a screw structure, snap structure, or other structure enabling connection with each other.

As shown in FIG. 2, in the embodiment explained above, the mounting parts 117b of the reinforcement plate 117 are arranged in only the width direction of the housing, but the flat part 117a is arranged to face all sides of the outer periphery of the display portion 121, and the two-sided tape 114 and the print region of the protective plate 113 are arranged to face all sides of the outer periphery in the same way. Accordingly, the protective plate 113 will be adhered to the bottom part 115 of the front case 102a and the flat part 117a of the reinforcement plate 117 over the entire periphery, and the housing opening 116 is closed with the entire periphery sealed by the protective plate 113. In this way, by closure by the protective plate 113 sealing the housing opening 116 of the front case 102a, entry of dust etc. to the inside of the housing through a clearance between the protective plate 113 and the front case 102a from the outside of the housing can be suppressed. Further, the display device 120 is arranged at the front case 102a in a state where the front surface (bottom surface shown in FIG. 5) of the display portion 121 is made to abut against the back surface (top surface shown in FIG. 5) of the flat part 117a of the reinforcement plate 117 over the entire periphery, therefore entry of dust etc. to the front surface (bottom surface shown in FIG. 5) of the display portion 121 through a clearance between the display device 120 and the reinforcement plate 117 from the inside of the housing can be suppressed.

Further, in the embodiment explained above, the reinforcement plate 117 used as the mounting member arranged at the inner circumference of the housing opening 116 of the front case 102a is constituted by sheet metal provided with conductivity or other metal and constituted so as to be conductive with the ground part of the circuit board 131. Therefore, even in a case where static electricity charged to the hand of a user holding the mobile phone 100 enters the inside of the housing through a clearance between the protective plate 113 and the recess 130 of the front case 102a, this static electricity will be grounded at the ground part of the circuit board 131 through the reinforcement plate 117 having conductivity. Accordingly, it can be suppressed that this static electricity is conducted to the display device 120 and other electric parts inside the housing and influences on the each electric parts, and damage to the electric parts etc. can be suppressed. Note that, the reinforcement plate 117 is made to directly abut against the ground part of the circuit board 131, but may also be constituted so as to be conductively connected with the ground part of the circuit board 131 through a metal member or the like arranged at the display device 120. Further, when the reinforcement plate 117 is constituted by a non-conductive material such as a resin, the same effects can be exhibited by a constitution giving conductivity to the outer circumference by conductive paint or vapor deposition of metal.

As explained above, in the mobile phone 100 in the embodiment explained above, the flat part 117a of the reinforcement plate 117 mounted on the front case 102a is arranged at the inner circumference of the housing opening 116 formed in the front case 102a, and the two-sided tape 114 is arranged on this flat part 117a and the bottom part (peripheral edge of the housing opening 116) 115 of the front case 102a. The protective plate 113 used as the cover closing the housing opening 116 is adhered and fastened to the bottom part 115 and the flat part 117a by the two-sided tape 114. The display device 120 is arranged inside the housing so that the display portion 121 faces the protective plate 113 with at least a portion of the display device 120 inserted in the housing opening 116. Therefore, the bonding area of the protective plate 113 to the front case 102a by the two-sided tape 114 can be increased. Further, the adhesion strength of the protective plate 113 on the front case 102a can be improved. Accordingly, even in a case where impact is applied to the mobile phone 100 at the time of dropping etc., detachment of the protective plate 113 from the front case 102a can be prevented.

Further, the protective plate 113 is not adhered to the display portion 121, but adhered to the reinforcement plate 117 mounted on the front case 102a. Accordingly, even in the case where the mobile phone 100 is disassembled for repair etc., stress acting upon the display portion 121 by the bonding force of the two-sided tape 114 can be suppressed, and damage of the display device 120 can be prevented.

By the constitution in which the thickness of the flat part 117a of the reinforcement plate 117 is made thinner than the thickness of the bottom part 115 of the front case 102a (depth of the housing opening 116) and the display device 120 is arranged inside the housing with at least a portion of the display device 120 inserted in the housing opening 116, the protective plate 113 and the display device 120 can be arranged in close contact and the housing can be made thinner. Further, by employing a constitution forming the recess 130 in the front case 102a and inserting the protective plate 113 in the recess 130, projection of the protective plate 113 from the front surface of the housing, and exposure of the two-sided tape 114 can be prevented, so the appearance of the housing can be improved.

Further, due to the constitution in which the top surface 118 of the flat part 117a of the reinforcement plate 117 arranged at the inner circumference of the housing opening 116 of the front case 102a is made the same plane as the top surface 125 of the bottom part 115 of the recess 130, the bonding of the protective plate 113 to the bottom part 115 and the flat part 117a by the two-sided tape 114 can be made stronger. Further, the movement of the reinforcement plate 117 to the outside of the housing (lower side shown in FIG. 5) is limited by engagement of the mounting parts 117b and the projecting parts 123 of the front case 102a. Therefore, even in a case where impact is applied to the mobile phone 100 at the time of dropping or the like and stress to the outside of the housing acts upon the reinforcement plate 117 from the display device 120 etc., detachment of the protective plate 113 from the bottom part 115 of the front case 102a and the flat part 117a of the reinforcement plate 117 can be prevented because it is suppressed that the reinforcement plate 117 moves to the outside of the housing and presses the protective plate 113 against the outside of the housing.

Above, an embodiment was explained based on an illustrated example, but the present invention is not limited to the above embodiment and can be appropriately modified within the scope of the claims. For example, the reinforcement plate 117 was mounted on the front case 102a by fitting the mounting parts 117b to the projecting parts 123 of the front case 102a, but the constitution is not limited to this. The reinforcement plate 117 may be mounted on the front case 102a by using insert molding, fusion bonding, or the like. Further, the reinforcement plate 117 is preferably mounted on the front case 102a by a strength greater than the adhesive strength of the two-sided tape 114 (stress when the protective plate 113 is detached). Note that the reinforcement plate 117 used as the mounting member need only be providing at least a function of increasing the bonding area of the protective plate 113 to the front case 102a by being mounted on the front case 102a. A function of reinforcing the strength of the front case 102a is not always necessary. However, in the case where the reinforcement function is provided as in the above embodiment, the housing strength at the periphery of the housing opening 116 can be improved, and a detachment of the protective plate 113 due to impact can be prevented.

Further, the invention is not limited to a flip-open type mobile phone 100 and can also be applied to a horizontally rotation type, biaxial hinge type, or slide type mobile phone or a straight type mobile phone. Further, other than a mobile phone, it can be applied to for example a personal digital assistant, a notebook type portable personal computer, or other portable terminal or other electronic device. Further, in the above embodiment, the protective plate 113 was adhered to the front case 102a and the reinforcement plate 117 by using two-sided tape 114, but a constitution bonding by using a bonding member other than two-sided tape (for example, adhesive paste or the like) may be employed as well.

Note that the front case 102a of the present embodiment corresponds to the “case member” of the present invention. Further, the protective plate 113 of the present embodiment corresponds to the “cover” of the present invention. Further, the bottom part 115 of the present embodiment described above corresponds to the “peripheral edge” of the present invention. Further, the housing opening 116 of the present embodiment corresponds to the “opening” of the present invention. Further, the reinforcement plate 117 of the present embodiment corresponds to the “mounting member” of the present invention. Further, the flat part 117a of the present embodiment corresponds to the “bonding part” of the present invention. Further, the projecting parts 123 of the present embodiment correspond to the “limit member” of the present invention. Further, the top surface 118 and top surface 125 of the present embodiment correspond to the “bonding surfaces” of the present invention. Further, the projecting parts 123 of the present embodiment correspond to the “projecting parts” of the present invention. Further, the circuit board 131 of the present embodiment corresponds to the “circuit board” of the present invention.

1. An electronic device comprising:
a housing with an opening;
a mounting member arranged at an inner circumference of the opening and mounted on the housing;
a cover adhered to a peripheral edge of the opening of the housing and to the mounting member and covering the opening; and
a display arranged inside the housing so as to face the cover in a state at least partially inserted in the opening.

2. An electronic device as set forth in claim 1, wherein
a thickness of the mounting member is thinner than a thickness of the peripheral edge of the opening.

3. An electronic device as set forth in claim 1, wherein
the housing has a recess which is recessed inwardly and in which the opening is formed, and
the cover is fit in the recess.

4. An electronic device as set forth in claim 1, wherein
the mounting member is arranged so that a bonding surface with the cover in the mounting member and a bonding surface with the cover at the peripheral edge of the opening become the same plane.

5. An electronic device as set forth in claim 1, wherein
the housing has a limit member limiting movement of the mounting member in an outward direction of the housing.

6. An electronic device as set forth in claim 1, wherein
the mounting member has conductivity and is connected to a ground part being inside the housing.

7. An electronic device as set forth in claim 1, wherein
the display is arranged inside the housing in a state abutting against a surface, which is on the inside of the housing, of the mounting member.

8. An electronic device as set forth in claim 1, wherein
the housing has a case member in which the opening is formed,
the case member has projecting parts formed to project out to the inside of the housing, and
the mounting member is clamped by the projecting parts and a circuit board arranged inside the housing.

9. An electronic device as set forth in claim 1, wherein
the mounting member has a plate-shaped bonding part which is arranged at the inner circumference of the opening and is bonded with the cover, and
the bonding part is arranged over the entire periphery of the opening.

10. An electronic device comprising:
a housing accommodating a display and circuit board and in which an opening is formed;
a mounting member arranged at an inner circumference of the opening; and
a cover covering the opening, wherein
the mounting member is mounted on the housing,
the cover is bonded to a peripheral edge of the opening of the housing and to the mounting member, and
the display is arranged inside the housing so as to face the cover in a state at least partially inserted in the opening.

11. A mobile phone comprising:
a housing having an operation key, a microphone, and a speaker, wherein
the receiver housing is provided with
a case member having an opening formed therein,
a mounting member arranged at an inner circumference of the opening and mounted on the case member,
a cover bonded to a peripheral edge of the opening of the case member and to the mounting member and covering the opening, and
a display arranged inside the housing so as to face the cover in a state at least partially inserted in the opening.
